(19) United States
(12) Patent Application Publication
(10) Pub. No.: US 2026/0304863 A1
(43) Pub. Date: Oct. 1, 2026

(54) VERTICAL THIN FILM TRANSISTOR AND MANUFACTURING METHOD THEREOF

(71) Applicant: AUO Corporation, Hsinchu City (TW)

(72) Inventors: Yi-Da He, Hsinchu City (TW); Jian-Jie Chen, Hsinchu City (TW); Cheng-Wei Jiang, Hsinchu City (TW); Kuo-Kuang Chen, Hsinchu City (TW)

(73) Assignee: AUO Corporation, Hsinchu City (TW)

(21) Appl. No.: 19/339,319

(22) Filed: Sep. 25, 2025

(30) Foreign Application Priority Data
Mar. 31, 2025 (TW) 114112399

(51) Int. Cl. H10D 62/10; H10D 30/01; H10D 30/67

(52) U.S. Cl. CPC H10D 62/117; H10D 30/0318; H10D 30/6728

(57) ABSTRACT

A vertical thin film transistor includes first, second, and third semiconductor layers, a sacrificed layer, a first gate, source, and drain electrodes. The first semiconductor layer is disposed on a substrate and has first heavily doped and extension portions. The sacrificed layer covers the extension portion and exposes the first heavily doped portion. The second semiconductor layer is disposed on the sacrificed layer and has a second heavily doped portion. The third semiconductor layer covers and is in contact with portions of the first and second heavily doped portions and a sidewall of the sacrificed layer. In a direction perpendicular to the substrate, the second heavily doped portion is overlapped with the extension portion, the first gate electrode is overlapped with the second heavily doped and extension portions and the third semiconductor layer. The source and drain electrodes are electrically connected to the first and second heavily doped portions, respectively.

### CROSS-REFERENCE TO RELATED APPLICATION

This application claims the priority benefit of Taiwan application serial no. 114112399, filed on Mar. 31, 2025. The entirety of the above-mentioned patent application is hereby incorporated by reference herein and made a part of this specification.

### BACKGROUND OF THE INVENTION

### Field of the Invention

The invention relates to a transistor and a manufacturing method thereof, and in particular to a vertical thin film transistor and a manufacturing method thereof.

### Description of Related Art

To meet the demands of high-resolution, low-power, and high-frequency display operation, short-channel thin film transistors (TFTs) having high switching speed, high electron mobility, and smaller size have become a key development focus. In particular, vertical TFTs are particularly popular due to also having high integration, thus further reducing layout space and manufacturing costs. However, existing vertical TFTs still face challenges, such as poor process stability, preventing existing vertical TFTs from achieving the expected operating electrical performance.

### SUMMARY OF THE INVENTION

The invention provides a vertical thin film transistor having an ultra-short channel and stable operating electrical properties.

The invention provides a manufacturing method of a vertical thin film transistor having better process stability and production yield.

The vertical thin film transistor of the invention includes a first semiconductor layer, a sacrificed layer, a second semiconductor layer, a third semiconductor layer, a first gate electrode, a source electrode, and a drain electrode. The first semiconductor layer is disposed on a substrate and has a first heavily doped portion and an extension portion. The sacrificed layer covers the extension portion of the first semiconductor layer and exposes the first heavily doped portion. The second semiconductor layer is disposed on the sacrificed layer and has a second heavily doped portion. In a direction perpendicular to the substrate, the second heavily doped portion is overlapped with the extension portion of the first semiconductor layer. The third semiconductor layer covers and is in contact with a portion of the first heavily doped portion, a sidewall of the sacrificed layer, and a portion of the second heavily doped portion. In the direction perpendicular to the substrate, the first gate electrode is overlapped with the second heavily doped portion, the extension portion, and the third semiconductor layer. The source first gate electrode and the drain first gate electrode are electrically connected to the first heavily doped portion and the second heavily doped portion, respectively.

The invention provides a manufacturing method of a vertical thin film transistor, including forming a first semiconductor material layer on a substrate, forming a sacrificed layer on the first semiconductor material layer to cover a first portion of the first semiconductor material layer and expose a second portion of the first semiconductor material layer, forming a second semiconductor material layer on the sacrificed layer, performing a heavy doping process on the second portion of the first semiconductor material layer and the second semiconductor material layer, forming a third semiconductor layer on the first semiconductor material layer and the second semiconductor material layer after the heavy doping process is completed, performing a laser annealing process on the first semiconductor material layer and the second semiconductor material layer, forming a gate electrode on the substrate, and forming a source electrode and a drain electrode. After the heavy doping process and the laser annealing process are completed, the first portion and the second portion of the first semiconductor material layer respectively form an extension portion and a first heavily doped portion of the first semiconductor layer, and the second semiconductor material layer forms a second heavily doped portion of the second semiconductor layer. The source electrode and the drain electrode are electrically connected to the first heavily doped portion and the second heavily doped portion, respectively.

Based on the above, in the vertical thin film transistor and the manufacturing method thereof of an embodiment of the invention, the first semiconductor layer, in addition to the first heavily doped portion, also includes the extension portion extended between the sacrificed layer and the substrate. The provision of the extension portion may prevent the subsequently formed third semiconductor layer from sinking into the gap between the sacrificed layer and the first heavily doped portion produced due to insufficient process precision and failing to form an effective short channel. In other words, the process margin of the sacrificed layer may be significantly improved, thereby enhancing the process and operational stability of the vertical thin film transistor.

### BRIEF DESCRIPTION OF THE DRAWINGS

FIG. 1 is a schematic cross-sectional view of a vertical thin film transistor according to the first embodiment of the invention.

FIGS. 2A to 2F are schematic cross-sectional views of a manufacturing process of the vertical thin film transistor of FIG. 1.

FIGS. 3A to 3E are schematic cross-sectional views of another manufacturing process of the vertical thin film transistor of FIG. 1.

FIG. 4 is a schematic cross-sectional view of a vertical thin film transistor according to the second embodiment of the invention.

FIGS. 5A to 5F are schematic cross-sectional views of a manufacturing process of the vertical thin film transistor of FIG. 4.

FIG. 6 is a schematic cross-sectional view of a vertical thin film transistor according to the third embodiment of the invention.

FIG. 7 is a schematic cross-sectional view of a vertical thin film transistor according to the fourth embodiment of the invention.

FIGS. 8A to 8G are cross-sectional views of a manufacturing process of the vertical thin film transistor of FIG. 7.

FIG. 9 is a schematic cross-sectional view of an element substrate according to an embodiment of the invention.

FIGS. 10A to 10H are schematic cross-sectional views of a manufacturing process of the element substrate of FIG. 9.

### DESCRIPTION OF THE EMBODIMENTS

As used herein, “about,” “approximately,” “essentially,” or “substantially” include the value and the mean value within an acceptable deviation range for the particular value as determined by one of ordinary skill in the art, taking into account the measurement in question and the particular amount of error associated with the measurement (i.e., the limitations of the measurement system). For example, “about” may mean within one or a plurality of standard deviations of the value, or within, for example, ±30%, ±20%, ±15%, ±10%, or ±5%. Furthermore, as used herein, a more acceptable deviation range or standard deviation may be selected for “about,” “approximately,” “essentially,” or “substantially” depending on the measured property, cutting property, or other properties, instead of applying one standard deviation to all properties.

In the accompanying drawings, the thickness of layers, films, panels, regions, etc., is exaggerated for clarity. It should be understood that when an element such as a layer, film, region, or substrate is referred to as being “on” or “connected to” another element, the element may be directly on the other element or connected to the other element, or an intermediate element may also exist. In contrast, when an element is referred to as being “directly on another element” or “directly connected to” another element, there are no intermediate elements. As used herein, “connection” may refer to physical and /or electrical connection. Furthermore, “electrical connection” may mean the presence of other elements between two elements.

Additionally, relative terms such as “lower” or “bottom” and “upper” or “top” may be used herein to describe the relationship between one element to another element, as shown in the figures. It should be understood that relative terms are intended to include different orientations of the device in addition to the orientation shown in the figures. For example, if the device in one of the figures is turned over, an element described as being on the “lower” side of the other elements would be oriented on the “upper” side of the other elements. Thus, the exemplary term “lower” may include both “lower” and “upper” orientations, depending on the particular orientation of the figure. Similarly, if the device in one of the figures is turned over, an element described as being “below” or “beneath” other elements would be oriented “above” the other elements. Thus, the exemplary terms “above” or “below” may include both “above” and “below” orientations.

Exemplary embodiments are described herein with reference to cross-sectional illustrations that are schematic representations of idealized embodiments. Thus, variations of the shapes of the figures as a result of, for example, manufacturing techniques and/or tolerances, are to be expected. Thus, the embodiments described herein should not be construed as limited to the specific shapes of the regions as shown herein, but rather include deviations in shapes that result, for example, from manufacturing. For example, a region shown or described as flat may typically have rough and/or nonlinear features. Furthermore, sharp angles that are shown may be rounded. Accordingly, the regions shown in the figures are schematic in nature, and the shapes thereof are not intended to show the precise shape of the regions and are not intended to limit the claims.

Reference will now be made in detail to exemplary embodiments of the invention, and examples of the exemplary embodiments are illustrated in the accompanying drawings. Whenever possible, the same reference numerals are used in the drawings and the description to refer to the same or similar portions.

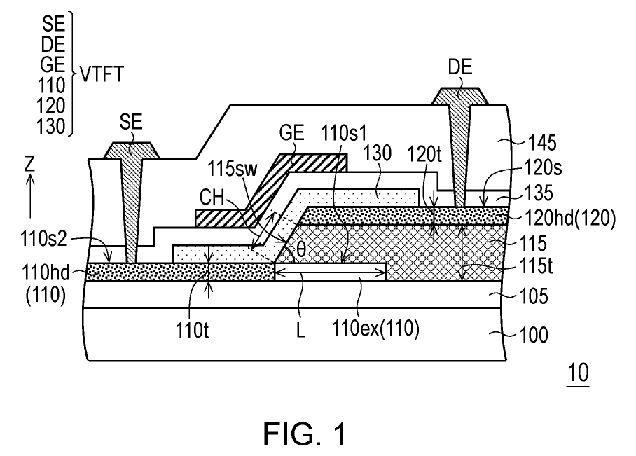

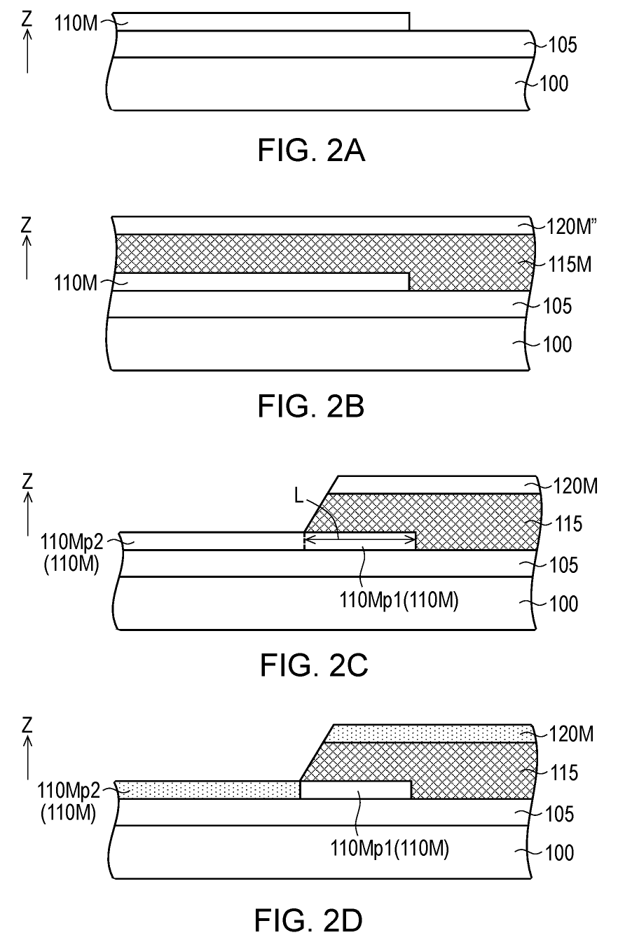

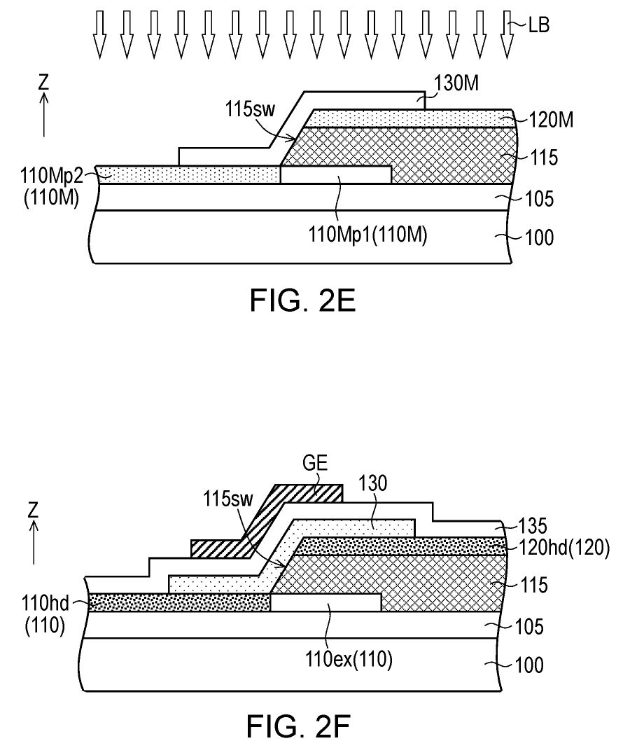

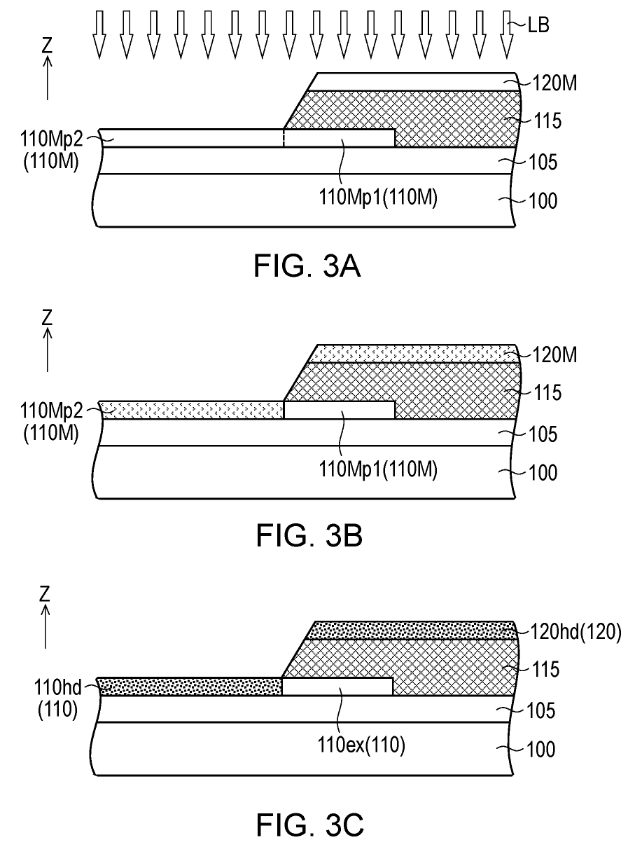

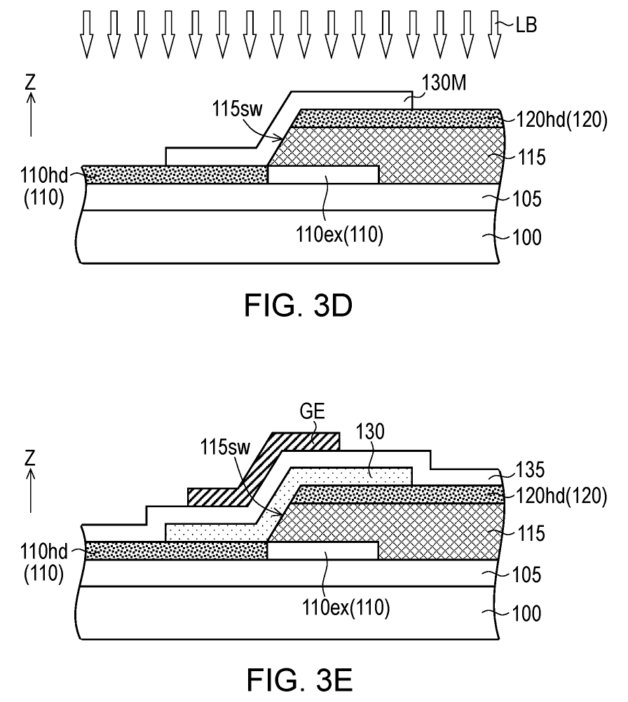

FIG. 1 is a schematic cross-sectional view of a vertical thin film transistor according to the first embodiment of the invention. FIGS. 2A to 2F are schematic cross-sectional views of a manufacturing process of the vertical thin film transistor of FIG. 1. FIGS. 3A to 3E are schematic cross-sectional views of another manufacturing process of the vertical thin film transistor of FIG. 1.

Referring to FIG. 1, a vertical thin film transistor VTFT includes a first semiconductor layer 110, a sacrificed layer 115, a second semiconductor layer 120, and a third semiconductor layer 130. The first semiconductor layer 110 is disposed on a substrate 100 and includes a first heavily doped portion 110hd and an extension portion 110ex. In the present embodiment, a buffer layer 105 may be disposed between the first semiconductor layer 110 and the substrate 100. The material of the buffer layer 105 is, for example, an inorganic material (e.g., silicon oxide, silicon nitride, silicon oxynitride, or a stacked layer of at least two of the materials). In some embodiments, the buffer layer 105 may be a single-layer structure or a multi-layer structure, but is not limited thereto.

The sacrificed layer 115 is disposed on the substrate 100. It should be mentioned that, the sacrificed layer 115 covers the extension portion 110ex of the first semiconductor layer 110 and exposes the first heavily doped portion 110hd. The sidewall of the extension portion 110ex is in contact with the sidewall of the first heavily doped portion 110hd. From another perspective, the extension portion 110ex of the first semiconductor layer 110 is extended out from the first heavily doped portion 110hd and extended below the sacrificed layer 115. For example, an extension length L of the extension portion 110ex below the sacrificed layer 115 may be greater than or equal to 0.5 μm, but is not limited thereto.

The first semiconductor layer 110 may have a single-layer structure or a multi-layer structure. In a preferred embodiment, the material of the first heavily doped portion 110hd of the first semiconductor layer 110 may include polysilicon semiconductor material, and the material of the extension portion 110ex may include amorphous silicon semiconductor material, but is not limited thereto. The material of the sacrificed layer 115 includes, for example, silicon oxide or silicon nitride, but is not limited thereto.

The second semiconductor layer 120 is disposed on the sacrificed layer 115 and includes a second heavily doped portion 120hd. In a direction (e.g., a direction Z) perpendicular to the substrate 100, the second heavily doped portion 120hd of the second semiconductor layer 120 is overlapped with the extension portion 110ex of the first semiconductor layer 110. For example, in the present embodiment, the dopant concentration of the second heavily doped portion 120hd is substantially the same as the dopant concentration of the first heavily doped portion 110hd, but is not limited thereto. The second semiconductor layer 120 may have a single-layer structure or a multi-layer structure. In a preferred embodiment, the material of the second semiconductor layer 120 may include polysilicon semiconductor material, but is not limited thereto.

The third semiconductor layer 130 covers and is in contact with a portion of the first heavily doped portion 110hd, a sidewall 115sw of the sacrificed layer 115, and a portion of the second heavily doped portion 120hd. For example, in the present embodiment, the third semiconductor layer 130 may be in contact with a portion of a surface 110s2 of the first heavily doped portion 110hd facing away from the substrate 100 and a portion of a surface 120s of the second heavily doped portion 120hd facing away from the substrate 100. The third semiconductor layer 130 may have a single-layer structure or a multi-layer structure.

In a preferred embodiment, the material of the third semiconductor layer 130 may include polysilicon semiconductor material, but is not limited thereto. Specifically, the portion of the third semiconductor layer 130 in contact with the sidewall 115sw of the sacrificed layer 115 may define a channel region CH of the vertical thin film transistor VTFT. In the present embodiment, the length of the channel region CH may be less than 3 μm. In other words, the vertical thin film transistor VTFT of the present embodiment may be a thin film transistor having an ultra-short channel.

In a preferred embodiment, a thickness 115t of the sacrificed layer 115 may be greater than or equal to twice a thickness 110t of the first heavily doped portion 110hd or a thickness 120t of the second heavily doped portion 120hd, wherein the defining direction of the thickness of each layer is, for example, along a direction (e.g., the direction Z) perpendicular to the substrate 100, but is not limited thereto. To ensure the vertical thin film transistor VTFT has sufficient channel length, an included angle θ between the sidewall 115sw of the sacrificed layer 115 and a surface 110s1 of the extension portion 110ex of the first semiconductor layer 110 connected to the sacrificed layer 115 is less than 90 degrees. In a preferred embodiment, the included angle θ may be less than 60 degrees, for example, any angle within a range of 30 degrees to 60 degrees.

First, it should be noted that, since the first semiconductor layer 110 includes, in addition to the first heavily doped portion 110hd, the extension portion 110ex extended between the sacrificed layer 115 and the substrate 100, a gap between the sacrificed layer 115 and the first heavily doped portion 110hd formed due to insufficient process precision and causing the subsequently formed third semiconductor layer 130 to sink into the resulting gap and failing to form an effective short channel may be effectively prevented. In other words, the provision of the extension portion 110ex significantly improves the process margin of the sacrificed layer 115, thereby enhancing the process and operational stability of the vertical thin film transistor VTFT.

Furthermore, the vertical thin film transistor VTFT further includes a gate electrode GE, a source electrode SE, and a drain electrode DE disposed on the substrate 100. For example, in the present embodiment, the gate electrode GE may be disposed at a side of the third semiconductor layer 130 facing away from the substrate 100. In other words, the vertical thin film transistor VTFT of the present embodiment may be a top-gate thin film transistor, but is not limited thereto. More specifically, in the direction Z, the gate electrode GE may be overlapped with the first heavily doped portion 110hd, the extension portion 110ex, the second heavily doped portion 120hd, and the third semiconductor layer 130.

In the present embodiment, a dielectric layer 135 may be disposed between the third semiconductor layer 130 and the gate electrode GE. The dielectric layer 135 may be a single-layer structure or a multi-layer structure, and the material thereof may include, for example, silicon oxide, silicon nitride, or other suitable insulating materials. For example, the gate electrode GE may be covered with an insulating layer 145 on top, and the source electrode SE and the drain electrode DE are disposed on the insulating layer 145. The material of the insulating layer 145 includes, for example, an inorganic material (e.g., silicon oxide, silicon nitride, silicon oxynitride, other suitable materials, or a stacked layer of at least two of the materials), an organic material (e.g., polyester (PET), polyolefin, polyacrylic, polycarbonate, polyalkylene oxide, polyphenylene, polyether, polyketone, polyol, polyaldehyde, other suitable materials, or a combination thereof), or other suitable materials, or a combination thereof.

In the present embodiment, the source electrode SE and the drain electrode DE may penetrate the insulating layer 145 and the dielectric layer 135 to be electrically connected to the first heavily doped portion 110hd of the first semiconductor layer 110 and the second heavily doped portion 120hd of the second semiconductor layer 120, respectively. The gate electrode GE, the source electrode SE, and the drain electrode DE may each be a single-layer structure or a multi-layer structure, and the material thereof includes, for example, transparent conductive material (such as metal oxide), non-transparent conductive material (such as molybdenum, aluminum, copper, titanium, chromium, etc.), a combination thereof, or other suitable conductive materials.

It should be noted that the vertical thin film transistor VTFT of the present embodiment may be applied onto an element substrate 10, and the element substrate 10 may be used as a driver circuit board of a display panel. The display panel may be a self-luminous display panel, such as an organic light-emitting diode (OLED) display panel or a micro light-emitting diode (micro-LED) display panel, but is not limited thereto. In other applications, the display panel may also be a non-self-luminous display panel, such as a liquid-crystal display (LCD) panel or an electrophoretic display (EPD) panel.

For example, the vertical thin film transistor VTFT may be used as a driver element in the display area of a display panel, such as a driver element of a display sub-pixel, but is not limited thereto. In other applications, the vertical thin film transistor VTFT may also be used as a driver element in the non-display area of a display panel, such as a driver element of a peripheral circuit.

The following is an exemplary description of a manufacturing method of the vertical thin film transistor VTFT. Referring to FIG. 2A, the buffer layer 105 and a first semiconductor material layer 110M are sequentially formed on the substrate 100. Preferably, the first semiconductor material layer 110M is formed by, for example, amorphous silicon semiconductor material. However, the invention is not limited thereto. In another embodiment, the first semiconductor material layer 110M may be formed directly on the substrate 100, thereby omitting the provision of the buffer layer 105.

Please refer to FIGS. 2B and 2C. Then, a sacrificed material layer 115M is formed on the first semiconductor material layer 110M, and a second semiconductor material layer 120M” is formed on the sacrificed material layer 115M. A patterning process is performed on the sacrificed material layer 115M and the second semiconductor material layer 120M” to form a stacked structure of the sacrificed layer 115 and the second semiconductor material layer 120M, wherein the patterning process is, for example, a photolithography process, but is not limited thereto.

It should be noted that the sacrificed layer 115 formed by the patterning process covers a first portion 110Mp1 of the first semiconductor material layer 110M and exposes a second portion 110Mp2 of the first semiconductor material layer 110M, as shown in FIG. 2C. Since the first portion 110Mp1 of the first semiconductor material layer 110M is reserved for coverage by the sacrificed layer 115, a gap between the sacrificed layer 115 and the first semiconductor material layer 110M formed due to insufficient process precision may be prevented, thereby ensuring that the subsequently manufactured third semiconductor layer may form a short channel. In the present embodiment, in order to account for deviations between the process and the design, the extension length L of the first portion 110Mp1 of the first semiconductor material layer 110M below the sacrificed layer 115 may be greater than or equal to 0.5 μm, but is not limited thereto. The extension length L may be adjusted according to the actual process deviation.

Referring to FIG. 2D, a heavy doping process is performed on the second portion 110Mp2 of the first semiconductor material layer 110M and the second semiconductor material layer 120M. Since the heavy doping process is performed simultaneously on the second portion 110Mp2 of the first semiconductor material layer 110M and the second semiconductor material layer 120M, the dopant concentration of the second portion 110Mp2 of the first semiconductor material layer 110M is substantially equal to the dopant concentration of the second semiconductor material layer 120M.

Referring to FIGS. 2E and 2F, after the heavy doping process is completed, a third semiconductor material layer 130M is formed on the first semiconductor material layer 110M, and a laser annealing process is performed on the first semiconductor material layer 110M, the second semiconductor material layer 120M, and the third semiconductor material layer 130M. After the laser annealing process is completed, the first portion 110Mp1 and the second portion 110Mp2 of the first semiconductor material layer 110M respectively form the extension portion 110ex and the first heavily doped portion 110hd of the first semiconductor layer 110, the second semiconductor material layer 120M forms the second heavily doped portion 120hd of the second semiconductor layer 120, and the third semiconductor material layer 130M forms the third semiconductor layer 130.

For example, in the present embodiment, the amorphous silicon semiconductor material of the second portion 110Mp2 of the first semiconductor material layer 110M and the second semiconductor material layer 120M is transformed into a polycrystalline silicon semiconductor material after being irradiated by laser beam. However, since the first portion 110Mp1 of the first semiconductor material layer 110M is covered by the second semiconductor material layer 120M on top, the amount of exposure to a laser beam LB received by the first portion 110Mp1 is insufficient. As a result, the first portion 110Mp1 of the first semiconductor material layer 110M still retains the composition of the amorphous silicon semiconductor material after the laser annealing process is completed.

Next, the gate electrode GE is formed on the substrate 100. In the present embodiment, the manufacturing method of the vertical thin film transistor VTFT of FIG. 1 may further include forming a dielectric layer 135 to cover the third semiconductor layer 130, wherein the gate electrode GE is formed on the dielectric layer 135. Referring to FIGS. 2F and 1, after the manufacture of the gate electrode GE is completed, an insulating layer 145 is formed to cover the gate electrode GE and the dielectric layer 135, and the source electrode SE and the drain electrode DE are formed on the insulating layer 145, wherein the source electrode SE and the drain electrode DE penetrate the insulating layer 145 and the dielectric layer 135 to be electrically connected to the first heavily doped portion 110hd of the first semiconductor layer 110 and the second heavily doped portion 120hd of the second semiconductor layer 120, respectively.

At this point, the manufacture of the vertical thin film transistor VTFT of FIG. 1 is completed.

However, the invention is not limited thereto. In another manufacturing process of the vertical thin film transistor VTFT of FIG. 1, the number of the laser annealing process may be two. For example, after the second semiconductor material layer 120M and the sacrificed layer 115 are formed and before the heavy doping process is performed, the first semiconductor material layer 110M and the second semiconductor material layer 120M may be subjected to a first laser annealing process, as shown in FIGS. 3A and 3B. Only after the first laser annealing process is completed is the heavy doping process performed on the second portion 110Mp2 of the first semiconductor material layer 110M and the second semiconductor material layer 120M, as shown in FIGS. 3B and 3C.

After the heavy doping process is completed, the third semiconductor material layer 130M is formed on the first semiconductor layer 110 and the second semiconductor layer 120, and a second laser annealing process is performed on the third semiconductor material layer 130M to form the third semiconductor layer 130, as shown in FIGS. 3D and 3E. Since the steps of forming the first semiconductor material layer 110M, the second semiconductor material layer 120M, and the sacrificed layer 115 and the method of forming the gate electrode GE, the source electrode SE, and the drain electrode DE are all similar to those of the manufacturing method of the above embodiments, detailed descriptions may be found in the relevant sections of the above embodiments and are not repeated here.

Another embodiment is listed below to illustrate the invention in detail, wherein the same members are marked with the same reference numerals, and the description of the same technical content is omitted. For the omitted portions, please refer to the above embodiments which are not repeated below.

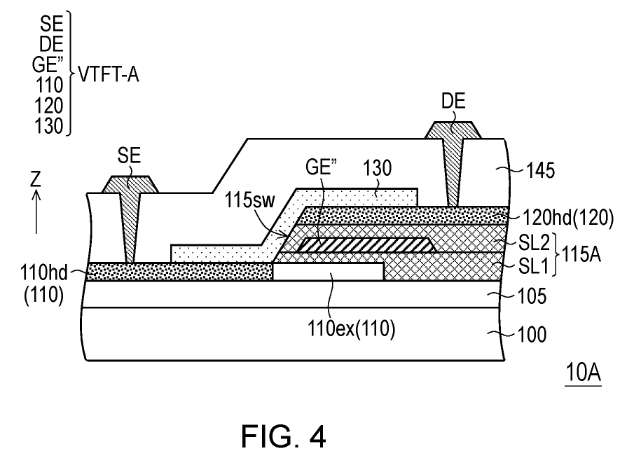

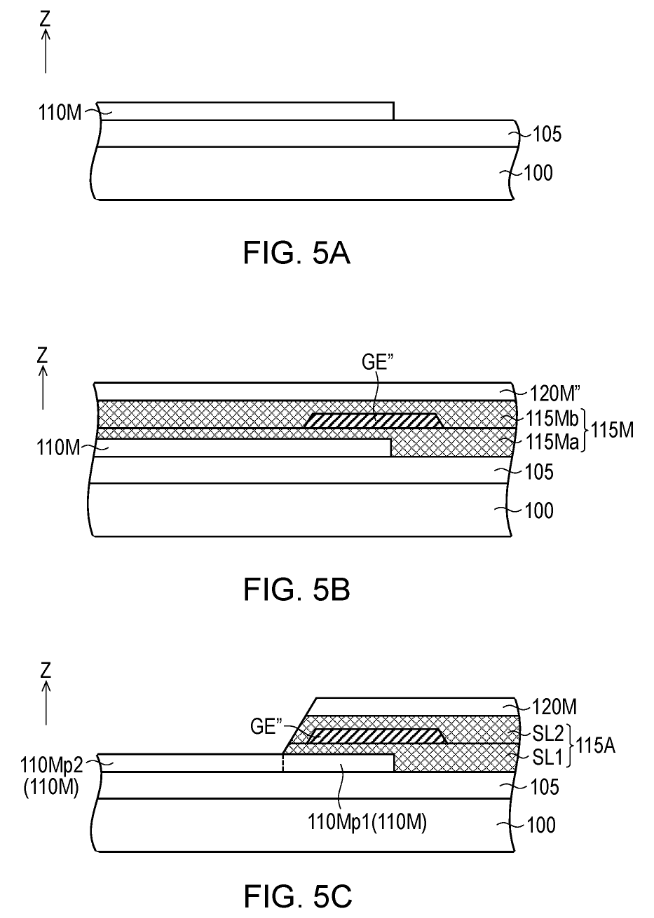

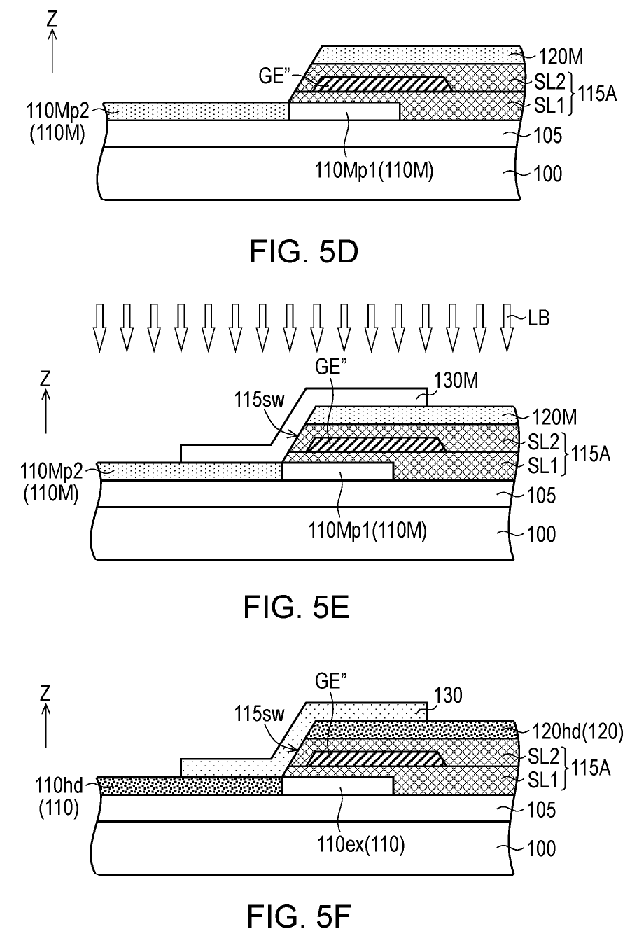

FIG. 4 is a schematic cross-sectional view of a vertical thin film transistor according to the second embodiment of the invention. FIG. 5A to FIG. 5F are schematic cross-sectional views of a manufacturing process of the vertical thin film transistor of FIG. 4. Referring to FIG. 4, the vertical thin film transistor VTFT-A of the element substrate 10A of the present embodiment differs from the vertical thin film transistor VTFT of FIG. 1 in that the position of the gate electrode is different.

Specifically, a gate electrode GE” of the vertical thin film transistor VTFT-A may be optionally disposed below the third semiconductor layer 130. That is, the vertical thin film transistor VTFT-A of the present embodiment may be a bottom-gate thin film transistor. In detail, in the present embodiment, a sacrificed layer 115A has a first sublayer SL1 and a second sublayer SL2, and the gate electrode GE” is sandwiched between the first sublayer SL1 and the second sublayer SL2. Therefore, in the direction Z, the gate electrode GE” is overlapped with the extension portion 110ex, the second heavily doped portion 120hd, and the third semiconductor layer 130, but is not overlapped with the first heavily doped portion 110hd. Moreover, since the gate electrode GE” is covered in the sacrificed layer 115A, the third semiconductor layer 130 of the present embodiment is not covered by the dielectric layer 135 in FIG. 1 on top.

The following is an exemplary description of a manufacturing method of the vertical thin film transistor VTFT-A. Referring to FIG. 5A, first, the buffer layer 105 and the first semiconductor material layer 110M are sequentially formed on the substrate 100. Preferably, the first semiconductor material layer 110M is formed by, for example, amorphous silicon semiconductor material. However, the invention is not limited thereto. In another embodiment, the first semiconductor material layer 110M may be formed directly on the substrate 100, thereby omitting the provision of the buffer layer 105.

Please refer to FIGS. 5B and 5C. Then, the sacrificed material layer 115M and the gate electrode GE” are formed on the first semiconductor material layer 110M, and the second semiconductor material layer 120M” is formed on the sacrificed material layer 115M. In particular, the step of forming the sacrificed material layer 115M may include sequentially forming a first sub-sacrificed material layer 115Ma and a second sub-sacrificed material layer 115Mb on the first semiconductor material layer 110M. It should be mentioned that the gate electrode GE” is formed after the first sub-sacrificed material layer 115Ma is formed and before the second sub-sacrificed material layer 115Mb is formed.

A patterning process is performed on the sacrificed material layer 115M and the second semiconductor material layer 120M” to form a stacked structure of the sacrificed layer 115A and the second semiconductor material layer 120M, wherein the patterning process is, for example, a photolithography process, but is not limited thereto. It should be noted that the sacrificed layer 115A formed by the patterning process covers the first portion 110Mp1 of the first semiconductor material layer 110M and exposes the second portion 110Mp2 of the first semiconductor material layer 110M, as shown in FIG. 5C. Since the first portion 110Mp1 of the first semiconductor material layer 110M is reserved for coverage by the sacrificed layer 115A, a gap between the sacrificed layer 115A and the first semiconductor material layer 110M formed due to insufficient process precision may be prevented, thereby ensuring that the subsequently manufactured third semiconductor layer may form a short channel.

Referring to FIG. 5D, a heavy doping process is performed on the second portion 110Mp2 of the first semiconductor material layer 110M and the second semiconductor material layer 120M. Since the heavy doping process is performed simultaneously on the second portion 110Mp2 of the first semiconductor material layer 110M and the second semiconductor material layer 120M, the dopant concentration of the second portion 110Mp2 of the first semiconductor material layer 110M is substantially equal to the dopant concentration of the second semiconductor material layer 120M.

Referring to FIGS. 5E and 5F, after the heavy doping process is completed, the third semiconductor material layer 130M is formed on the first semiconductor material layer 110M, and a laser annealing process is performed on the first semiconductor material layer 110M, the second semiconductor material layer 120M, and the third semiconductor material layer 130M. After the laser annealing process is completed, the first portion 110Mp1 and the second portion 110Mp2 of the first semiconductor material layer 110M respectively form the extension portion 110ex and the first heavily doped portion 110hd of the first semiconductor layer 110, the second semiconductor material layer 120M forms the second heavily doped portion 120hd of the second semiconductor layer 120, and the third semiconductor material layer 130M forms the third semiconductor layer 130.

For example, in the present embodiment, the amorphous silicon semiconductor material of the second portion 110Mp2 of the first semiconductor material layer 110M and the second semiconductor material layer 120M is transformed into a polycrystalline silicon semiconductor material after being irradiated by the laser beam. However, since the first portion 110Mp1 of the first semiconductor material layer 110M is covered by the second semiconductor material layer 120M on top, the amount of exposure to the laser beam LB received by the first portion 110Mp1 is insufficient. As a result, the first portion 110Mp1 of the first semiconductor material layer 110M still retains the composition of the amorphous silicon semiconductor material after the laser annealing process is completed.

Referring to FIGS. 5F and 4, after the manufacture of the third semiconductor layer 130 is completed, the insulating layer 145 is formed to cover the third semiconductor layer 130, and the source electrode SE and the drain electrode DE are formed on the insulating layer 145, wherein the source electrode SE and the drain electrode DE penetrate the insulating layer 145 to be electrically connected to the first heavily doped portion 110hd of the first semiconductor layer 110 and the second heavily doped portion 120hd of the second semiconductor layer 120, respectively. At this point, the manufacture of the vertical thin film transistor VTFT-A of FIG. 4 is completed.

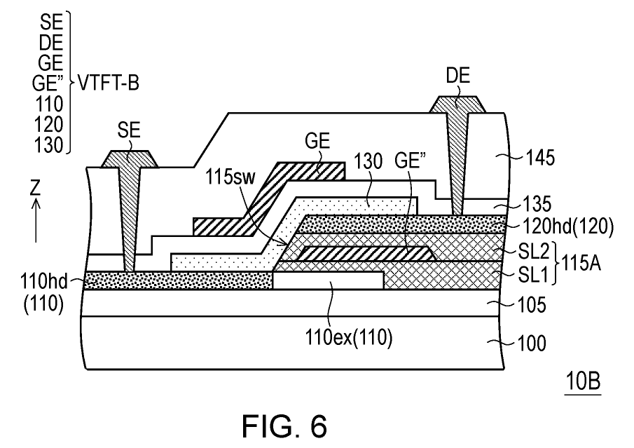

FIG. 6 is a schematic cross-sectional view of a vertical thin film transistor according to the third embodiment of the invention. Referring to FIG. 6, in an element substrate 10B of the present embodiment, a vertical thin film transistor VTFT-B may be a dual-gate thin film transistor. Specifically, the vertical thin film transistor VTFT-B of the present embodiment may simultaneously have the gate electrode GE located above the third semiconductor layer 130 and the gate electrode GE” located below the third semiconductor layer 130. Since the provision and the forming method of the gate electrode GE of the present embodiment are similar to the gate electrode GE of the vertical thin film transistor VTFT of FIG. 1, and the provision and the forming method of the gate electrode GE” are similar to the gate electrode GE” of the vertical thin film transistor VTFT-A of FIG. 4, detailed descriptions may be found in the relevant paragraphs of the above embodiments, which are not repeated here.

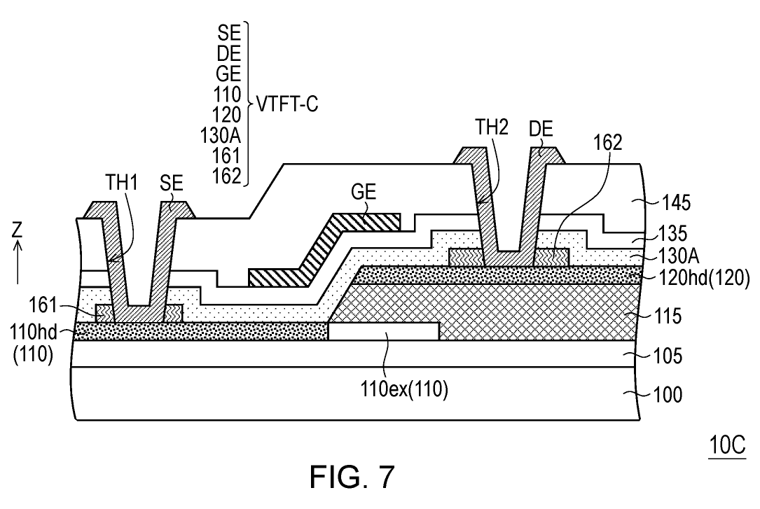

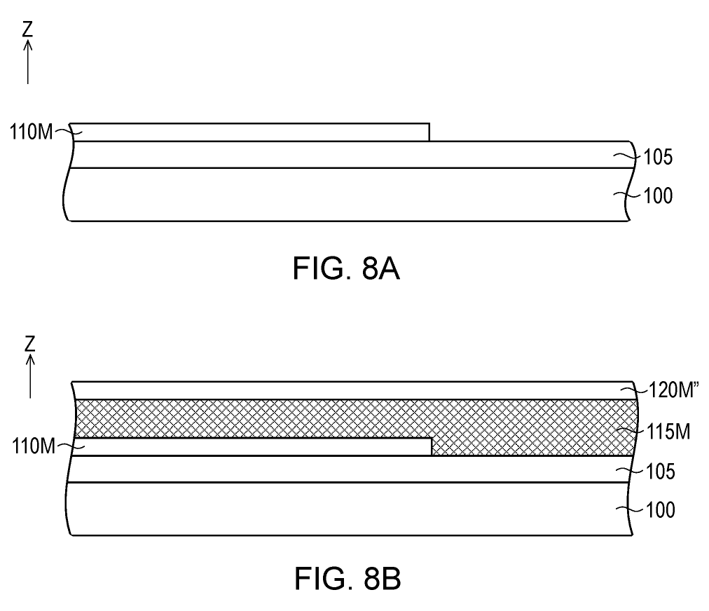

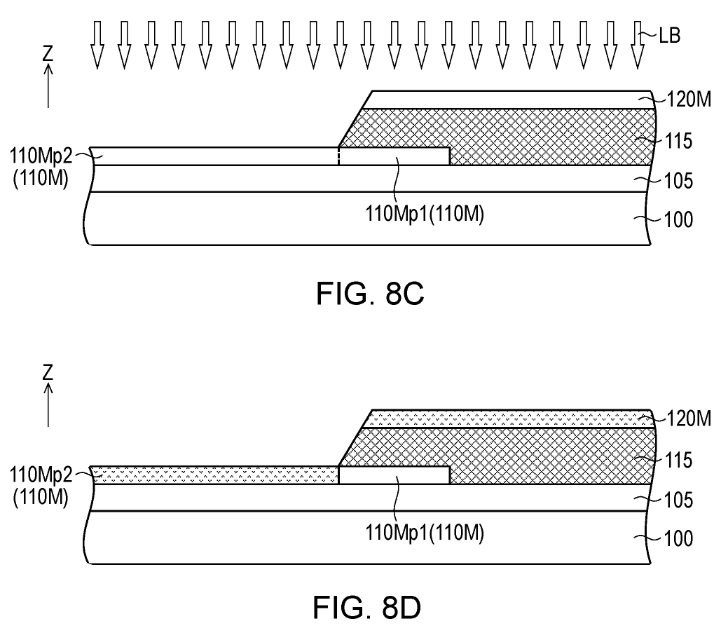

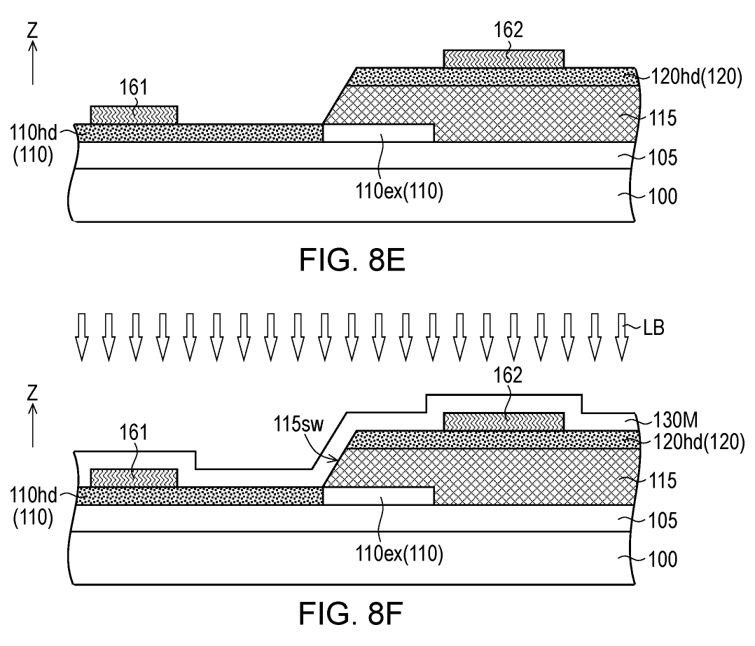

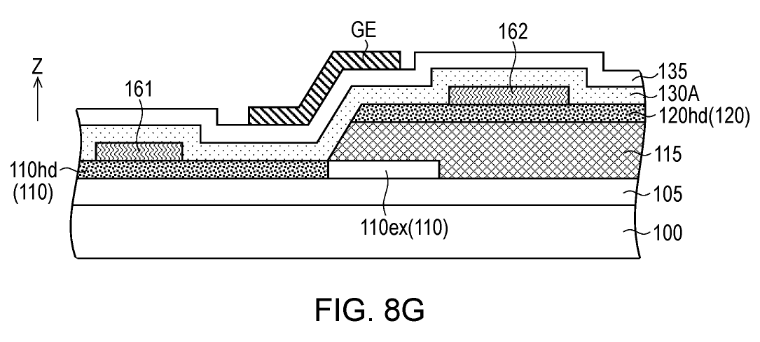

FIG. 7 is a schematic cross-sectional view of a vertical thin film transistor according to the fourth embodiment of the invention. FIGS. 8A to 8G are schematic cross-sectional views of a manufacturing process of the vertical thin film transistor of FIG. 7. Referring to FIG. 7, compared to the vertical thin film transistor VTFT of FIG. 1, a vertical thin film transistor VTFT-C of an element substrate 10C of the present embodiment further includes a first etching protection pattern 161 and a second etching protection pattern 162.

In the present embodiment, the first etching protection pattern 161 is disposed between the first heavily doped portion 110hd of the first semiconductor layer 110 and the third semiconductor layer 130A and in contact with the first heavily doped portion 110hd and the third semiconductor layer 130A. The second etching protection pattern 162 is disposed between the second heavily doped portion 120hd of the second semiconductor layer 120 and the third semiconductor layer 130A and in contact with the second heavily doped portion 120hd and the third semiconductor layer 130A. The source electrode SE penetrates the insulating layer 145, the dielectric layer 135, the third semiconductor layer 130A, and the first etching protection pattern 161 to be electrically connected to the first heavily doped portion 110hd of the first semiconductor layer 110. The drain electrode DE penetrates the insulating layer 145, the dielectric layer 135, the third semiconductor layer 130A, and the second etching protection pattern 162 to be electrically connected to the second heavily doped portion 120hd of the second semiconductor layer 120.

In other words, the source electrode SE may be electrically connected to the first heavily doped portion 110hd via a first contact hole TH1 of the insulating layer 145, the dielectric layer 135, the third semiconductor layer 130A, and the first etching protection pattern 161, and the drain electrode DE may be electrically connected to the second heavily doped portion 120hd via a second contact hole TH2 of the insulating layer 145, the dielectric layer 135, the third semiconductor layer 130A, and the second etching protection pattern 162. It should be noted that the orthographic projections of the first contact hole TH1 and the second contact hole TH2 on the substrate 100 are located in the orthographic projections of the first etching protection pattern 161 and the second etching protection pattern 162 on the substrate 100.

Since the etchant used in the etching process of the third semiconductor layer 130A does not have an etching selectivity ratio between the third semiconductor layer 130A and the first heavily doped portion 110hd (or the second heavily doped portion 120hd), the etching of the third semiconductor layer 130A performed to expose the first heavily doped portion 110hd and the second heavily doped portion 120hd is likely to cause damage or even rupture to the underlying heavily doped portion, resulting in failure of the electrical connection between each of the source electrode SE and the drain electrode DE and the heavily doped portion.

Therefore, the provision of the first etching protection pattern 161 and the second etching protection pattern 162 may prevent the heavily doped portion from being damaged by the etchant during the etching process of the third semiconductor layer 130A. Preferably, the material of the first etching protection pattern 161 and the second etching protection pattern 162 may include silicon oxide (SiO) or silicon nitride (SiN). From another perspective, during the etching process of the etching protection pattern, the etchant has an etching selectivity ratio between the material (e.g., SiO or SiN) of the etching protection pattern and the material (e.g., Si) of the heavily doped portion, thereby preventing the heavily doped portion from being damaged by the etchant during the etching process of the etching protection pattern.

The following is an exemplary description of a manufacturing method of a vertical thin film transistor VTFT-C. Referring to FIG. 8A, first, the buffer layer 105 and the first semiconductor material layer 110M are sequentially formed on the substrate 100. Preferably, the first semiconductor material layer 110M is formed by, for example, amorphous silicon semiconductor material. However, the invention is not limited thereto. In another embodiment, the first semiconductor material layer 110M may be formed directly on the substrate 100, thereby omitting the provision of the buffer layer 105.

Please refer to FIGS. 8B and 8C. Then, the sacrificed material layer 115M is formed on the first semiconductor material layer 110M, and the second semiconductor material layer 120M” is formed on the sacrificed material layer 115M. A patterning process is performed on the sacrificed material layer 115M and the second semiconductor material layer 120M” to form a stacked structure of the sacrificed layer 115 and the second semiconductor material layer 120M, wherein the patterning process is, for example, a photolithography process, but is not limited thereto.

First, it should be noted that in the manufacturing process of the vertical thin film transistor VTFT-C of the present embodiment, the number of the laser annealing process may be two. For example, after the second semiconductor material layer 120M and the sacrificed layer 115 are formed and before the heavy doping process is performed, a first laser annealing process may be performed on the first semiconductor material layer 110M and the second semiconductor material layer 120M first, as shown in FIGS. 8C and 8D. Only after the first laser annealing process is completed is the heavy doping process performed on the second portion 110Mp2 of the first semiconductor material layer 110M and the second semiconductor material layer 120M, as shown in FIGS. 8D and 8E.

After the heavy doping process is completed, the first etching protection pattern 161 and the second etching protection pattern 162 are formed on the first heavily doped portion 110hd of the first semiconductor layer 110 and the second heavily doped portion 120hd of the second semiconductor layer 120, respectively. Next, the third semiconductor material layer 130M is formed to cover the first etching protection pattern 161, the second etching protection pattern 162, the first heavily doped portion 110hd, the second heavily doped portion 120hd, and the sidewall 115sw of the sacrificed layer 115, and a second laser annealing process is performed on the third semiconductor material layer 130M to form the third semiconductor layer 130A, as shown in FIGS. 8F and 8G.

Referring to FIGS. 8G and 7, after the manufacture of the third semiconductor layer 130A is completed, the gate electrode GE is formed on the substrate 100. In the present embodiment, the manufacturing method of the vertical thin film transistor VTFT-C of FIG. 7 may further include forming the dielectric layer 135 to cover the third semiconductor layer 130A, wherein the gate electrode GE is formed on the dielectric layer 135. After the manufacture of the gate electrode GE is completed, the insulating layer 145 is formed to cover the gate electrode GE and the dielectric layer 135, and the source electrode SE and the drain electrode DE are formed on the insulating layer 145, wherein the source electrode SE and the drain electrode DE penetrate the insulating layer 145, the dielectric layer 135, the third semiconductor layer 130A, and the etching protection pattern to be electrically connected to the first heavily doped portion 110hd of the first semiconductor layer 110 and the second heavily doped portion 120hd of the second semiconductor layer 120, respectively. At this point, the vertical thin film transistor VTFT-C of FIG. 7 is completed.

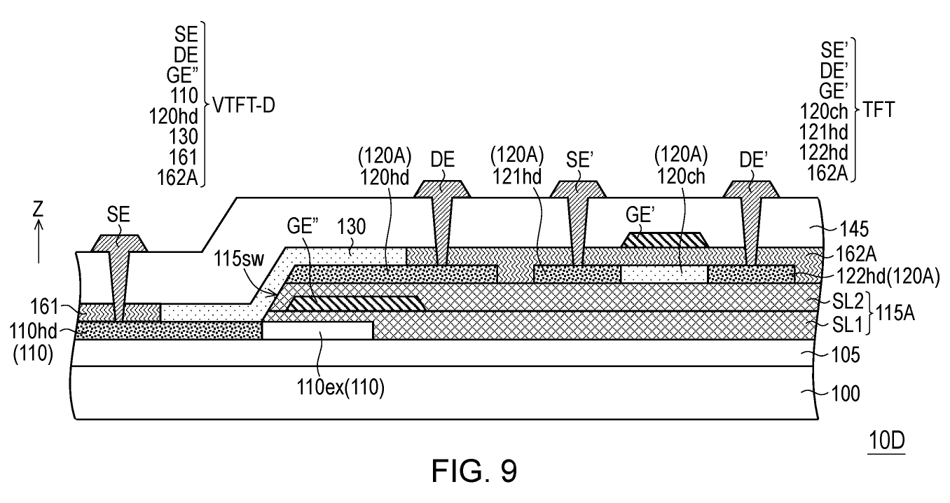

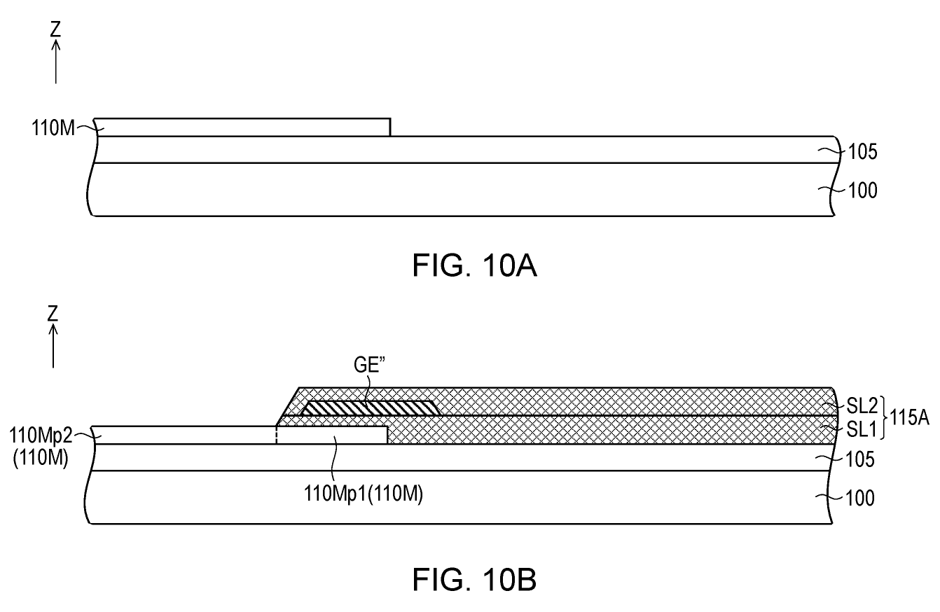

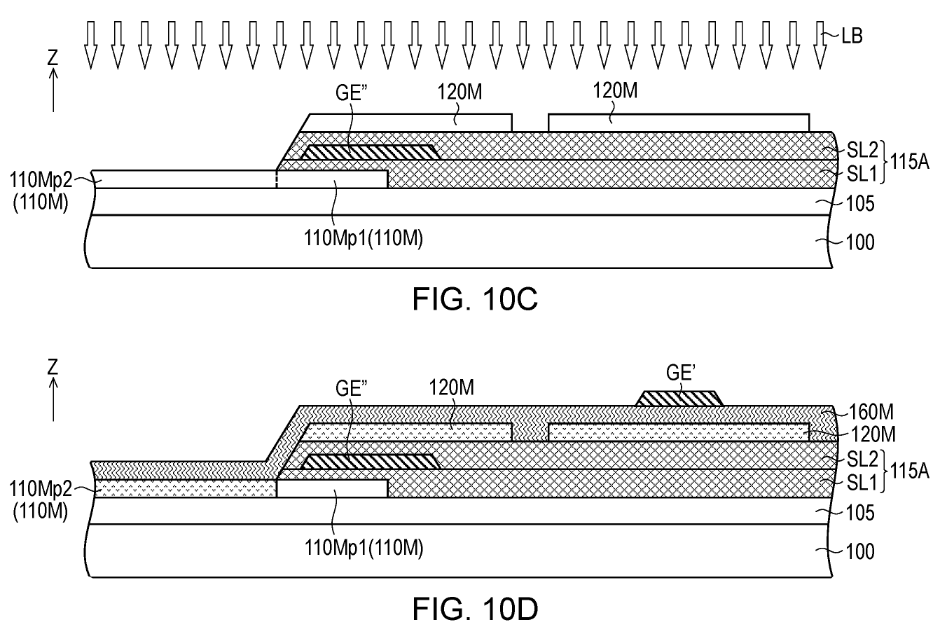

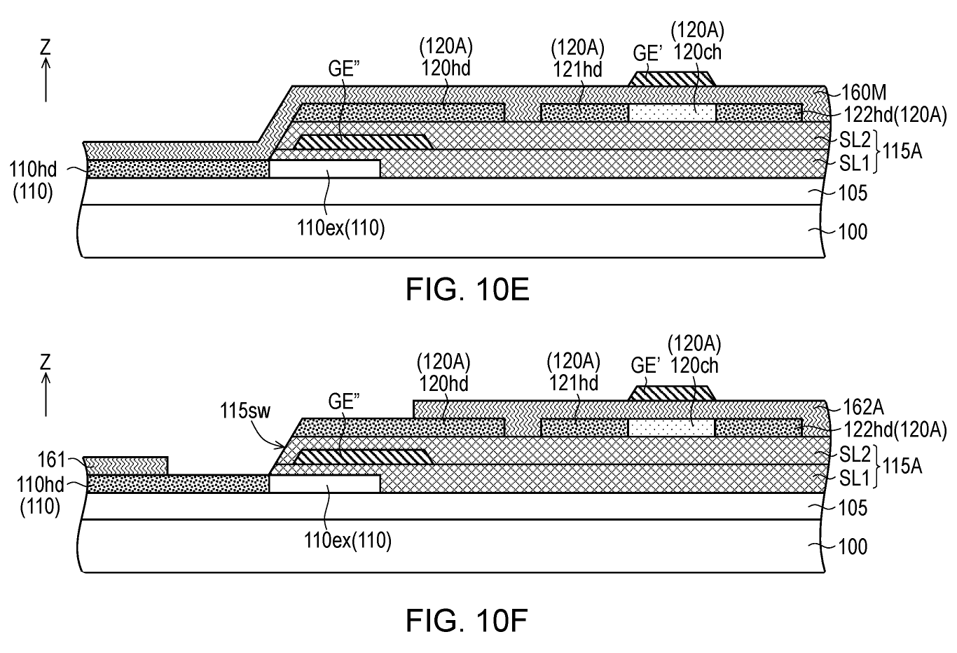

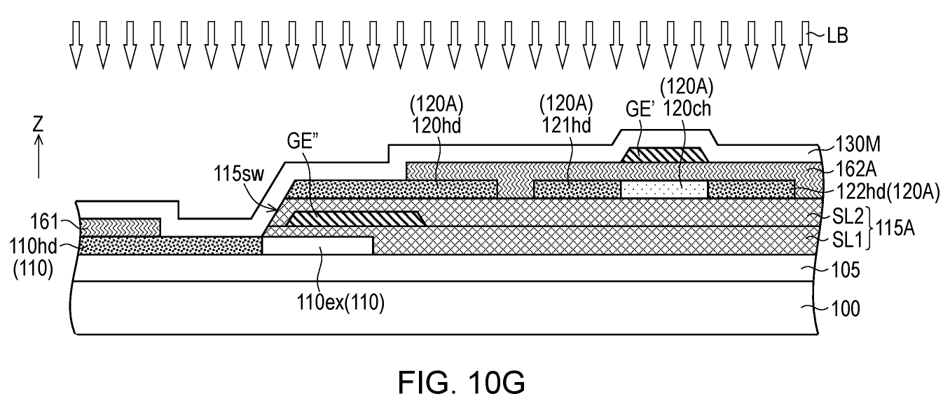

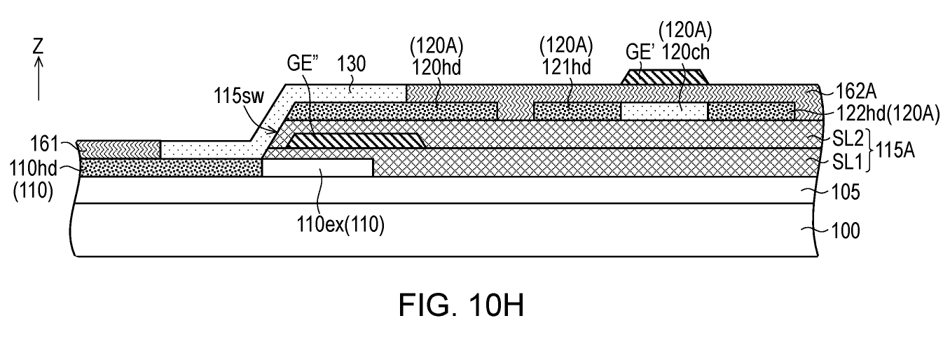

FIG. 9 is a schematic cross-sectional view of an element substrate of an embodiment of the invention. FIGS. 10A to 10H are schematic cross-sectional views of the manufacturing process of the element substrate of FIG. 9. Referring to FIG. 9, compared to the element substrate 10B of FIG. 6, an element substrate 10D of the present embodiment may also be provided with a thin film transistor TFT. Unlike the vertical thin film transistor VTFT-D, which is a bottom-gate thin film transistor, the thin film transistor TFT is a top-gate thin film transistor.

In the present embodiment, the thin film transistor TFT may include a source electrode SE’, a drain electrode DE’, a gate electrode GE’, a third heavily doped portion 121hd, a fourth heavily doped portion 122hd, and a channel 120ch. Specifically, the third heavily doped portion 121hd, the fourth heavily doped portion 122hd, and the channel 120ch of the thin film transistor TFT may be the same layer as the second heavily doped portion 120hd of the vertical thin film transistor VTFT-D, such as a second semiconductor layer 120A. A second etching protection pattern 162A covering a portion of the second heavily doped portion 120hd of the vertical thin film transistor VTFT-D, may also cover the third heavily doped portion 121hd, the fourth heavily doped portion 122hd, and the channel 120ch of the thin film transistor TFT. The gate electrode GE’ of the thin film transistor TFT is disposed on the second etching protection pattern 162A and covered by the insulating layer 145. The source electrode SE’ and the drain electrode DE’ of the thin film transistor TFT and the source electrode SE and the drain electrode DE of the vertical thin film transistor VTFT-D may be the same layer.

It should be noted that the second etching protection pattern 162A is disposed between the gate electrode GE’ and the second semiconductor layer 120A of the thin film transistor TFT of the present embodiment, so there is no need to further dispose the dielectric layer 135 shown in FIG. 1 to electrically isolate the gate electrode GE’ and the channel 120ch.

The following is an exemplary description of a manufacturing method of the vertical thin film transistor VTFT and the thin film transistor TFT. Referring to FIG. 10A, first, the buffer layer 105 and the first semiconductor material layer 110M are sequentially formed on a substrate 100. Preferably, the first semiconductor material layer 110M is formed by, for example, amorphous silicon semiconductor material. However, the invention is not limited thereto. In another embodiment, the first semiconductor material layer 110M may be formed directly on the substrate 100, thereby omitting the provision of the buffer layer 105.

Referring to FIG. 10B, the sacrificed layer 115A and the gate electrode GE” are then formed on the first semiconductor material layer 110M. Since the steps of forming the sacrificed layer 115A and the gate electrode GE” of the present embodiment are similar to those of the sacrificed layer 115A and the gate electrode GE” of FIG. 4, detailed descriptions may be found in the relevant paragraphs of the above embodiments which are not repeated here. It should be noted that the sacrificed layer 115A formed via the patterning process covers the first portion 110Mp1 of the first semiconductor material layer 110M and exposes the second portion 110Mp2 of the first semiconductor material layer 110M. Since the first portion 110Mp1 of the first semiconductor material layer 110M is reserved for coverage by the sacrificed layer 115A, a gap between the sacrificed layer 115A and the first semiconductor material layer 110M formed due to insufficient process precision may be prevented, thereby ensuring that the subsequently manufactured third semiconductor layer may form a short channel.

Referring to FIG. 10C, the second semiconductor material layer 120M is formed on the sacrificed layer 115A, and a laser annealing process is performed on the first semiconductor material layer 110M and the second semiconductor material layer 120M. As shown in FIG. 10D, next, an etching protection material layer 160M is formed to cover the first semiconductor material layer 110M and the second semiconductor material layer 120M, and another gate electrode GE’ is formed on the etching protection material layer 160M.

After the manufacture of the gate electrode GE’ is completed, a heavily doped process is performed on the second portion 110Mp2 of the first semiconductor material layer 110M and the second semiconductor material layer 120M, as shown in FIGS. 10D and 10E. The first portion 110Mp1 and the second portion 110Mp2 of the first semiconductor material layer 110M respectively form the extension portion 110ex and the first heavily doped portion 110hd of the first semiconductor layer 110. The second semiconductor material layer 120M forms the second heavily doped portion 120hd, the third heavily doped portion 121hd, and the fourth heavily doped portion 122hd of the second semiconductor layer 120A, and the undoped portion (i.e., the portion overlapped with the gate electrode GE’ along the direction Z) in the second semiconductor material layer 120M forms the channel 120ch.

Referring to FIGS. 10E and 10F, next, a patterning process is performed on the etching protection material layer 160M to form the first etching protection pattern 161 and the second etching protection pattern 162A and expose a portion of the first heavily doped portion 110hd, the sidewall 115sw of the sacrificed layer 115A, and a portion of the second heavily doped portion 120hd. After the patterning process of the etching protection material layer 160M is completed, the third semiconductor material layer 130M is formed to cover the etching protection pattern, a portion of the first heavily doped portion 110hd, the sidewall 115sw of the sacrificed layer 115A, and a portion of the second heavily doped portion 120hd, and another laser annealing process and patterning process are performed on the third semiconductor material layer 130M to form the third semiconductor layer 130, as shown in FIGS. 10G and 10H. In particular, the patterning process is, for example, a photolithography process, but is not limited thereto.

Since the etchant used in the etching process of the third semiconductor material layer 130M does not have an etching selectivity ratio between the third semiconductor material layer 130M and the first heavily doped portion 110hd (or the second heavily doped portion 120hd), the etching of the third semiconductor material layer 130M to expose a portion of the first heavily doped portion 110hd and a portion of the second heavily doped portion 120hd is likely to cause damage to or even rupture of the underlying heavily doped portion, resulting in failure of the electrical connection between each of the subsequently formed source electrode SE, drain electrode DE, source electrode SE’, and drain electrode DE’ and the heavily doped portion.

Therefore, the provision of the first etching protection pattern 161 and the second etching protection pattern 162A may prevent the heavily doped portion from being damaged by the etchant during the etching process of the third semiconductor material layer 130M. Preferably, the material of the first etching protection pattern 161 and the second etching protection pattern 162A may include silicon oxide (SiO) or silicon nitride (SiN). From another perspective, during the etching process of the etching protection pattern, the etchant has an etching selectivity ratio between the material (e.g., SiO or SiN) of the etching protection pattern and the material (e.g., Si) of the heavily doped portion, thereby preventing the heavily doped portion from being damaged by the etchant during the etching process of the etching protection pattern.

Since the method of forming the source electrode SE, the drain electrode DE, the source electrode SE’, and the drain electrode DE’ is similar to the manufacturing method of the vertical thin film transistor VTFT-A of FIG. 4, detailed descriptions may be found in the relevant sections of the above embodiments which are not repeated here. At this point, the manufacture of the vertical thin film transistor VTFT-D and the thin film transistor TFT of FIG. 9 is completed.

Based on the above, in the vertical thin film transistor and the manufacturing method thereof of an embodiment of the invention, the first semiconductor layer, in addition to the first heavily doped portion, also includes the extension portion extended between the sacrificed layer and the substrate. The provision of the extension portion may prevent the subsequently formed third semiconductor layer from sinking into the gap between the sacrificed layer and the first heavily doped portion formed due to insufficient process precision and failing to form an effective short channel. In other words, the process margin of the sacrificed layer may be significantly improved, thereby enhancing the process and operational stability of the vertical thin film transistor.

What is claimed is:

1. A vertical thin film transistor, comprising:
a first semiconductor layer disposed on a substrate and having a first heavily doped portion and an extension portion;
a sacrificed layer disposed on the substrate, and the sacrificed layer covers the extension portion and exposes the first heavily doped portion;
a second semiconductor layer disposed on the sacrificed layer and having a second heavily doped portion, wherein in a direction perpendicular to the substrate, the second heavily doped portion is overlapped with the extension portion of the first semiconductor layer;
a third semiconductor layer covering and in contact with a portion of the first heavily doped portion, a sidewall of the sacrificed layer, and a portion of the second heavily doped portion;
a first gate electrode disposed on the substrate, wherein in the direction perpendicular to the substrate, the first gate electrode is overlapped with the second heavily doped portion, the extension portion, and the third semiconductor layer; and
a source electrode and a drain electrode disposed on the substrate and electrically connected to the first heavily doped portion and the second heavily doped portion, respectively.

2. The vertical thin film transistor of claim 1, further comprising:
a dielectric layer disposed on the substrate and covering the third semiconductor layer, wherein the first gate electrode is disposed on the dielectric layer and overlapped with the first heavily doped portion in the direction perpendicular to the substrate.

3. The vertical thin film transistor of claim 2, wherein the extension portion of the first semiconductor layer is extended out from the first heavily doped portion.

4. The vertical thin film transistor of claim 2, wherein a thickness of the sacrificed layer is greater than or equal to twice a thickness of the first heavily doped portion or the second heavily doped portion.

5. The vertical thin film transistor of claim 2, further comprising:
a first etching protection pattern disposed between the first heavily doped portion and the third semiconductor layer and in contact with the first heavily doped portion and the third semiconductor layer; and
a second etching protection pattern disposed between the second heavily doped portion and the third semiconductor layer and in contact with the second heavily doped portion and the third semiconductor layer,
wherein the source electrode penetrates the third semiconductor layer and the first etching protection pattern to be electrically connected to the first heavily doped portion, and the drain electrode penetrates the third semiconductor layer and the second etching protection pattern to be electrically connected to the second heavily doped portion.

6. The vertical thin film transistor of claim 5, wherein the source electrode is electrically connected to the first heavily doped portion via a first contact hole, the drain electrode is electrically connected to the second heavily doped portion via a second contact hole, and orthographic projections of the first contact hole and the second contact hole on the substrate are located in orthographic projections of the first etching protection pattern and the second etching protection pattern on the substrate.

7. The vertical thin film transistor of claim 1, wherein the sacrificed layer has a first sublayer and a second sublayer, and the first gate is sandwiched between the first sublayer and the second sublayer.

8. The vertical thin film transistor of claim 7, wherein the extension portion of the first semiconductor layer is extended out from the first heavily doped portion.

9. The vertical thin film transistor of claim 7, wherein a thickness of the sacrificed layer is greater than or equal to twice a thickness of the first heavily doped portion or the second heavily doped portion.

10. The vertical thin film transistor of claim 7, further comprising:
a first etching protection pattern disposed between the first heavily doped portion and the third semiconductor layer and in contact with the first heavily doped portion and the third semiconductor layer; and
a second etching protection pattern disposed between the second heavily doped portion and the third semiconductor layer and in contact with the second heavily doped portion and the third semiconductor layer;
wherein the source electrode penetrates the third semiconductor layer and the first etching protection pattern to be electrically connected to the first heavily doped portion, and the drain electrode penetrates the third semiconductor layer and the second etching protection pattern to be electrically connected to the second heavily doped portion.

11. The vertical thin film transistor of claim 10, wherein the source electrode is electrically connected to the first heavily doped portion via a first contact hole, the drain electrode is electrically connected to the second heavily doped portion via a second contact hole, and orthographic projections of the first contact hole and the second contact hole on the substrate are located in orthographic projections of the first etching protection pattern and the second etching protection pattern on the substrate.

12. The vertical thin film transistor of claim 7, further comprising:
a dielectric layer disposed on the substrate and covering the third semiconductor layer; and
a second gate disposed on the dielectric layer and overlapped with the first heavily doped portion, the second heavily doped portion, the extension portion, and the third semiconductor layer in the direction perpendicular to the substrate.

13. The vertical thin film transistor of claim 1, wherein the extension portion of the first semiconductor layer has a surface connected to the sacrificed layer, and an included angle between the sidewall of the sacrificed layer and the surface of the extension portion is less than 60 degrees.

14. A manufacturing method of a vertical thin film transistor, comprising:
forming a first semiconductor material layer on a substrate;
forming a sacrificed layer on the first semiconductor material layer, and the sacrificed layer covers a first portion of the first semiconductor material layer and exposes a second portion of the first semiconductor material layer;
forming a second semiconductor material layer on the sacrificed layer;
performing a heavy doping process on the second portion of the first semiconductor material layer and the second semiconductor material layer;
forming a third semiconductor layer on the first semiconductor material layer and the second semiconductor material layer after the heavy doping process is completed;
performing a laser annealing process on the first semiconductor material layer and the second semiconductor material layer, wherein after the heavy doping process and the laser annealing process are completed, the first portion and the second portion of the first semiconductor material layer respectively form an extension portion and a first heavily doped portion of a first semiconductor layer, and the second semiconductor material layer forms a second heavily doped portion of a second semiconductor layer;
forming a gate electrode on the substrate; and
forming a source electrode and a drain electrode to electrically connect the first heavily doped portion and the second heavily doped portion, respectively.

15. The manufacturing method of the vertical thin film transistor of claim 14, wherein the laser annealing process is performed after the heavy doping process, and the step of forming the third semiconductor layer comprises:
forming a third semiconductor material layer; and
performing the laser annealing process on the third semiconductor material layer.

16. The manufacturing method of the vertical thin film transistor of claim 14, wherein the laser annealing process is performed before the heavy doping process, and the step of forming the third semiconductor layer comprises:
forming a third semiconductor material layer; and
performing another laser annealing process on the third semiconductor material layer.

17. The manufacturing method of the vertical thin film transistor of claim 14, further comprising:
forming a dielectric layer to cover the third semiconductor layer, wherein the gate electrode is formed on the dielectric layer.

18. The manufacturing method of the vertical thin film transistor of claim 14, wherein the step of forming the sacrificed layer comprises:
forming a first sub-sacrificed material layer and a second sub-sacrificed material layer in sequence on the first semiconductor material layer, wherein the gate electrode is formed after the first sub-sacrificed material layer is formed and before the second sub-sacrificed material layer is formed; and
performing a patterning process on the first sub-sacrificed material layer and the second sub-sacrificed material layer to form a first sublayer and a second sublayer of the sacrificed layer.

19. The manufacturing method of the vertical thin film transistor of claim 14, further comprising:
forming a first etching protection pattern and a second etching protection pattern on the first semiconductor material layer and the second semiconductor material layer respectively before the third semiconductor layer is formed.

20. The manufacturing method of the vertical thin film transistor of claim 19, wherein the first etching protection pattern and the second etching protection pattern are formed after the heavy doping process is completed.
